(19) United States
(12) Patent Application Publication
(10) Pub. No.: US 2015/0262879 A1
(43) Pub. Date: Sep. 17, 2015

(54) PLASMA DICING METHOD AND PLASMA DICING APPARATUS

(71) Applicant: Kabushiki Kaisha Toshiba, Tokyo (JP)

(72) Inventor: Takayuki Sakai, Nonoichi Ishikawa (JP)

(21) Appl. No.: 14/481,110

(22) Filed: Sep. 9, 2014

(30) Foreign Application Priority Data
Mar. 17, 2014 (JP) 2014-053705

(51) Int. Cl. H01L 21/78; C23C 16/513; H01J 37/32; H01L 21/67; H01L 21/3065

(52) U.S. Cl. CPC H01L 21/78; H01L 21/67069; H01L 21/3065; H01J 37/32532; H01J 37/32715; C23C 16/513; H01J 2237/332; H01J 2237/334

(57) ABSTRACT

According to one embodiment, the plasma dicing method includes a deposition process depositing a film on the dicing region and on the metal electrodes exposed to the pad opening in an atmosphere containing a plasma of a first gas. The plasma dicing method includes an etching process etching the film by applying a first bias power to a lower electrode supporting the wafer in an atmosphere containing a plasma of a second gas. The substrate is etched by reducing the first bias power to a second bias power when light emission due to etching of the substrate at the dicing region is detected during the etching process.

### CROSS-REFERENCE TO RELATED APPLICATION

This application is based upon and claims the benefit of priority from Japanese Patent Application No. 2014-053705, filed on Mar. 17, 2014; the entire contents of which are incorporated herein by reference.

### FIELD

Embodiments described herein relate generally to a plasma dicing method and a plasma dicing apparatus.

### BACKGROUND

With the miniaturization of electronic devices, advancements in miniaturization of semiconductor devices has brought demand for even thinner semiconductor elements. A thinner semiconductor element is susceptible to damage such as cracks or chipping in a dicing process which cause concern for, production yield. Instead of a mechanical cutting method using a blade as a method of dicing the thin semiconductor elements, a plasma dicing method for cutting a semiconductor wafer using plasma etching has been proposed.

In the plasma dicing method, after forming the semiconductor element on a substrate in a wafer state, a front face side or a back face side of the substrate is adhered to a support tape (sheet), a mask layer of a photoresist or metal is formed on the surface on the side opposite the support tape, and a mask pattern for plasma dicing is formed by removing the mask layer in a dicing region.

However, a complex process of high cost is required in forming the dicing mask pattern while the wafer is adhered to the support tape which can lead to an increase in overall cost of the dicing process.

### BRIEF DESCRIPTION OF THE DRAWINGS

FIG. 1 is a schematic view of a plasma dicing apparatus of an embodiment;

FIGS. 2A and 2B are schematic cross-sectional views of a wafer of the embodiment;

FIGS. 3A to 3D are schematic cross-sectional views showing a plasma dicing method of the embodiment; and

FIG. 4 is a timing chart showing the plasma dicing method of the embodiment.

### DETAILED DESCRIPTION

According to one embodiment, a plasma dicing method includes plasma etching a substrate at a dicing region between a plurality of semiconductor layers in a wafer. The wafer includes the substrate, the plurality of semiconductor layers formed on the substrate separated from each other, metal electrodes provided on each of the semiconductor layers, and a passivation film covering the semiconductor layers. The passivation film has pad openings exposing a portion of the metal electrodes. The plasma dicing method includes a deposition process depositing a film on the dicing region and on the metal electrodes exposed to the pad opening in an atmosphere containing a plasma of a first gas. The plasma dicing method includes an etching process etching the film by applying a first bias power to a lower electrode supporting the wafer in an atmosphere containing a plasma of a second gas. The substrate is etched by reducing the first bias power to a second bias power when light emission due to etching of the substrate at the dicing region is detected during the etching process.

Embodiments will be described below with reference to drawings. Note that the same reference numerals are applied for the same elements in each drawing.

After forming the semiconductor element by a wafer process, separately forming the mask pattern for plasma dicing can lead to increased cost. Therefore, according to the embodiment, passivation film for an element protection formed on the surface of the semiconductor element is also used as a mask when plasma dicing.

The passivation film covers a semiconductor layer of the semiconductor element and metal electrodes. Furthermore, the substrate of the dicing region is exposed without being covered by the passivation film. Furthermore, a portion of the metal electrode is also exposed from the passivation film and the exposed metal electrode becomes a pad that bears an electrical connection with an external circuit.

From a standpoint of production efficiency, the pad openings are formed collectively in the passivation film of all elements in a wafer state before dicing and the metal electrode is exposed.

Accordingly, an exposed portion of the metal electrode is exposed to the plasma during plasma dicing and there is a concern that the metal electrode will be sputtered by ions accelerated toward the wafer. It may cause failures such as short-circuit or the like if a sputtered metal component is scattered and adheres onto the passivation film.

Therefore, the embodiment provides a plasma dicing method and a plasma dicing apparatus that can prevent sputtering of the metal electrode exposed in the pad opening using the passivation film as a mask.

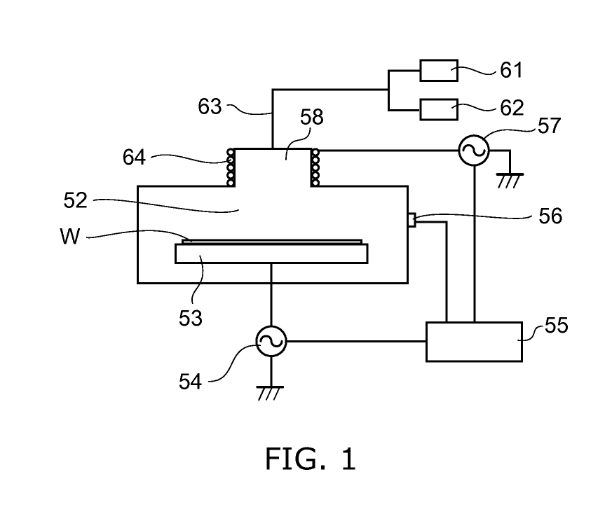

FIG. 1 is a schematic view of the plasma dicing apparatus of the embodiment.

A lower electrode 53 is provided in a processing chamber 52. The lower electrode 53 also serves as a support portion of a wafer W and the wafer Was the dicing target is supported on the lower electrode 53. Furthermore, the lower electrode 53 is connected to a high frequency power source 54 provided outside of the processing chamber 52 and bias power is applied from a high frequency power source 54 to the lower electrode 53.

The plasma dicing apparatus of the embodiment has, for example, a plasma generating mechanism of an inductively coupled plasma (ICP) type. A plasma generating unit 58 is provided on the top of the processing chamber 52. A coil 64 is wound around the periphery of the plasma generating unit 58 and a coil 64 is connected to a high frequency power source 57.

Alternatively, the plasma generating mechanism can be another mechanism such as a capacitive coupling type (parallel plate type), electron cyclotron resonance (ECR) type, or the like.

The plasma generating unit 58 is connected to a gas introduction pipe 63. The gas introduction pipe 63 is connected to a first gas supply source 61 and a second gas supply source 62.

Furthermore, a sensor 56 is provided outside of the processing chamber 52. The sensor 56 is a spectrometer, for example, to detect the light emission intensity associated with the plasma etching of the etched material.

Furthermore, the plasma dicing apparatus of the embodiment has a control unit 55. The control unit 55 controls the ON/OFF and the power of the high frequency power sources 54 and 57. Furthermore, the control unit 55 is connected to the sensor 56 and receives a detection signal (light emission intensity) of the sensor 56.

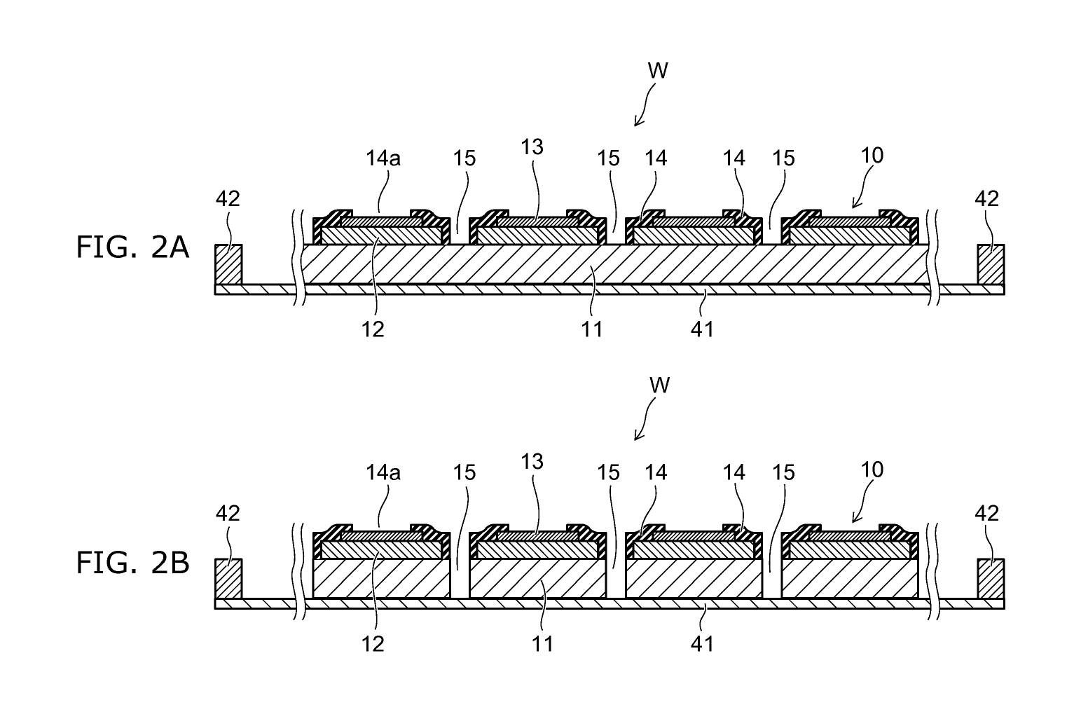

Next, FIG. 2A is a schematic cross-sectional view illustrating an example of the cross-section structure of the wafer W before dicing.

The wafer W has a substrate 11. The substrate 11 is, for example, a silicon (Si) substrate. A plurality of semiconductor elements 10 is formed on the substrate 11. Furthermore, the substrate 11 is also a component of the semiconductor element 10.

The semiconductor element 10 is a power device such as, for example, a metal-oxide-semiconductor field effect transistor (MOSFET), an insulated gate bipolar transistor (IGBT), a diode, and the like.

The semiconductor element 10 has a semiconductor layer 12, a metal electrode 13 provided on the semiconductor layer 12, and a passivation film 14 that covers the semiconductor element 10.

A plurality of semiconductor layers 12 is formed on the substrate 11 mutually separated from each other. The region between the separated semiconductor layers 12 becomes a dicing region 15. For example, the dicing region 15 is formed in a lattice pattern in the wafer state.

A side surface of the semiconductor layer 12 adjacent to the dicing region 15 is covered by the passivation film 14. The substrate 11 is exposed on the bottom of the dicing region 15.

Furthermore, a pad opening 14a is formed in the passivation film 14 on the surface of the semiconductor element 10 and a portion of the metal electrode 13 is exposed to the pad opening 14a. The metal electrode 13 is, for example, an aluminum (Al) electrode.

In the wafer W, potions other than the dicing region 15 and the pad opening 14a are protected by being covered by the passivation film 14. The passivation film 14 is, for example, a resin film such as a polymide or an inorganic film such as a silicon dioxide film.

Next, a plasma dicing method of the embodiment is described.

Operations of each element of the plasma dicing apparatus described below are controlled by the control unit 55.

The rear surface (the surface opposite the surface where metal electrode 13 is formed) of the substrate 11 is adhered to a dicing sheet (tape) 41 and the wafer W is supported by a dicing sheet 41. The dicing sheet 41 is set up an inner side of a frame 42, for example, having a ring shape.

The wafer W supported by the dicing sheet 41 is transported into the processing chamber 52 and supported on the lower electrode 53. The dicing region 15 and the metal electrode 13 side are faced upward.

The processing chamber 52 is reduced by a vacuum exhaust system, not illustrated, and gas is introduced into the plasma generating unit (plasma generating chamber) 58 from the gas introduction pipe 63. The plasma generating unit 58 leads to a space above the lower electrode 53.

Then, flowing a high frequency current from the high frequency power source 57 to a coil 64 generates inductively coupled plasma in the plasma generating unit 58 by a variable magnetic field of high frequency and high voltage. Furthermore, bias power is given (applied) to the lower electrode 53 from the high frequency power source 54.

An exhaust volume and a gas introduction rate are properly controlled and the plasma atmosphere of the desired gas is maintained under a desired reduced pressure in the processing chamber 52.

A plasma treatment of the embodiment includes, film deposition (deposition process) by chemical reaction under a plasma atmosphere and an etching process for anisotropically etching an etching object and a film formed by the deposition process. Protecting the side walls of the etching region by a film formed by the deposition process, and by advancing etching in the depth direction (thickness direction of the substrate 11), suppresses the spread in the width direction of the etching region.

A deposition process is first performed after transporting the wafer W, as described above, into the processing chamber 52. For example, the first gas is introduced to the plasma generating unit 58 from a gas supply source 61 and is converted into plasma. That is, a film including an element included in the first gas is deposited on the wafer W in the atmosphere that includes the plasma of the first gas.

The first gas includes, for example, fluorocarbon type gas. For example, C₄F₈ gas is introduced to the processing chamber 52 (plasma generating unit 58). Then, for example, CFx polymer is deposited on the wafer W.

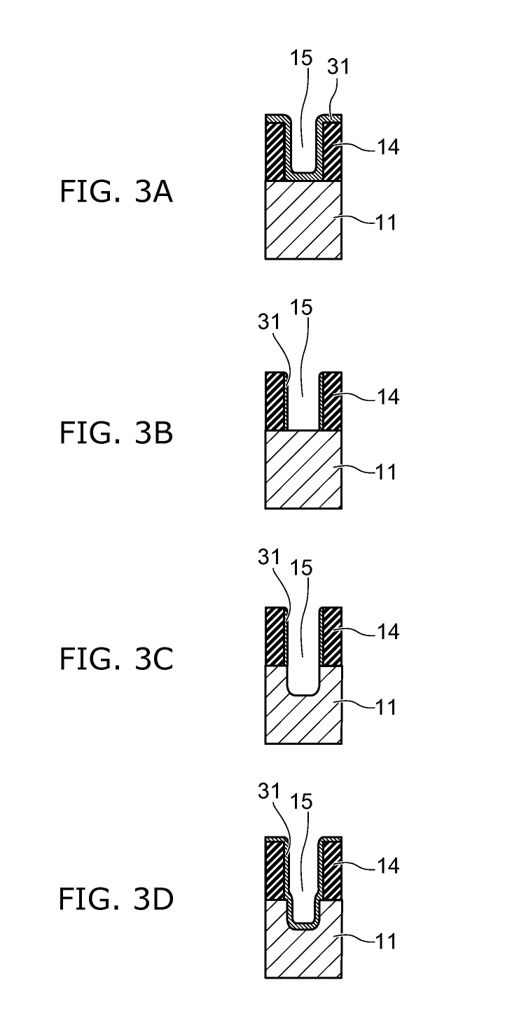

FIG. 3A is a schematic cross-sectional view of the dicing region 15. With the above deposition process, a film 31 is deposited conformally on the side wall and the bottom of the groove shaped dicing region 15. Furthermore, the film 31 is also deposited on the metal electrode 13 exposed to the pad opening 14a.

At this time, the film 31 is likely to deposit thicker on the metal electrode 13 of the pad opening 14a than on the substrate 11 of the bottom of the dicing region 15 because the aspect ratio (the ratio of the opening depth respective to the width) of the pad opening 14a is less than the aspect ratio of the dicing region 15.

Therefore, the thickness of the film 31 deposited on the substrate 11 of the dicing region 15 tends to be thinner than the thickness of the film 31 deposited on the metal electrode 13 of the pad opening 14a.

After the above deposition process is performed for a predetermined time, it is switched to the etching process under the control of the control unit 55. For example, the second gas is introduced to the plasma generating unit 58 from a gas supply source 62 and is converted into plasma. The second gas includes, for example, a fluorine-based gas. For example, SF₆ gas is introduced to the processing chamber 52 (plasma generating unit 58). By converting the SF₆ gas into plasma, a fluorine ion (F⁺) and a flourine radical are generated in the processing chamber 52.

Furthermore, a first bias power P1 is applied to the lower electrode 53 from the high frequency power source 54. By the first bias power P1, fluorine ion is, for example, accelerated toward the wafer W side and, as illustrated in FIG. 3B, the film 31 formed by the deposition process is anisotropically etched (reactive ion etching). Furthermore, the film 31 is etched isotropically by the action of the fluorine radicals. At this time, expansion of the etching width is suppressed by the film 31 formed by the above deposition process to the sidewalls (side face of the passivation film 14) of the dicing region 15.

The surface of the substrate 11 appears when the film 31 above the substrate 11 of the dicing region 15 is etched and removed. Then, according to the embodiment, the bias power applied to the lower electrode 53 is switched, and etching of the substrate 11 is performed.

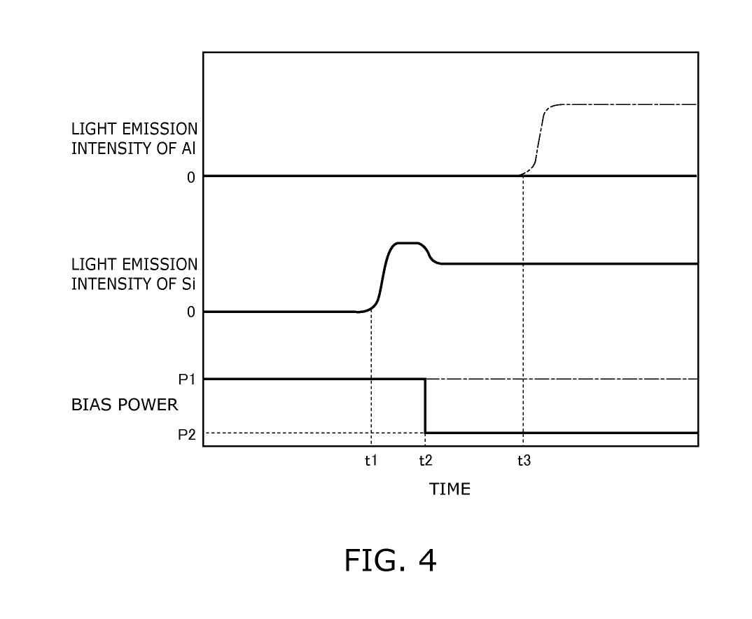

FIG. 4 is a timing chart showing the plasma dicing method of the embodiment. During the etching process, FIG. 4 represents a time change of the bias power applied to the lower electrode 53, a light emission intensity of silicon (Si) included in the substrate 11, and a light emission intensity of aluminum (Al) included in the metal electrode 13.

During the etching process after the deposition process, the surface of the substrate 11 is exposed, as illustrated in FIG. 3B, and etching of the substrate 11 starts once the film 31 deposited on dicing region 15 is removed. At this time, the light emission that accompanies plasma etching (reactive ion etching) of Si, which is the material of the substrate 11, occurs, and the light emission intensity of Si is detected by a sensor 56.

That is, the substrate 11 of the dicing region 15 begins to be etched at time t1 in FIG. 4, and the light emission intensity of Si is increased to a predetermined level from 0.

As previously mentioned, at the time t1 at which the substrate 11 began to be etched, a deposition film 31 is still on the metal electrode 13 of the pad opening 14a because the deposition film 31 on the metal electrode 13 of the pad opening 14a tends to be thicker than the deposition film 31 on the substrate 11 of the dicing region 15. That is, at the time t1, Al, which a material of the metal electrode 13, has not been plasma etched (sputtered) and the light emission intensity of Al is 0.

Upon receiving the detection signal of the sensor 56, the control unit 55 reduces the bias power applied to the lower electrode 53 if the rise of the light emission intensity of Si at time t1 is detected by the sensor 56.

That is, the first bias power P1, which has been applied to the lower electrode 53 during the etching of the deposition film 31, is reduced to a second bias power P2 which is lower than the first bias power P1.

In FIG. 4, from the detection time (t1) of the rise of the light emission intensity of Si, the bias power is reduced from P1 to P2, as indicated by solid line, at time t2 through the time lag (t2−t1) of the system control. Other conditions are the same as when etching the deposition film 31.

The energy of the incident ions relative to the wafer W is controlled by the bias power applied to the lower electrode 53.

The energy of the incident ions relative to the wafer W is lower than the energy to sputter the metal electrode 13 (Al) when the second bias power P2 is applied to the lower electrode 53.

In FIG. 4, the deposition film 31 deposited on the metal electrode 13 of the pad opening 14a disappears at time t3 and the plasma etching of Al begins if the etching process (same as the first bias power P1) continues without lowering the bias power as indicated by the one-dot chain line. Therefore, at time t3, the light emission intensity of Al as indicated by the dashed line rises to a predetermined level of 0.

That is, the exposed portion (Al) of the metal electrode 13 is exposed to plasma and Al ions are sputtered by the ions accelerating toward the wafer W. Further, it may cause failures such as a short-circuit if the sputtered Al is scattered and adheres to the passivation film 14.

In contrast to this, during the etching process in the embodiment, the detection signal (the light emission intensity of Si and the light emission intensity of Al) of the sensor 56 is monitored by the control unit 55, and after the etching of the Si (substrate 11) of the dicing region 15 has began, and before the Al (metal electrode 13) of the pad opening 14a is etched (sputtered), the bias power to be applied to the lower electrode 53 is reduced so that the energy of the incident ions relative to the wafer W is lower than the sputter threshold value of Al.

In the embodiment, it can be seen that the light emission intensity of Al, as indicated by the solid line in FIG. 4, does not rise and stays constant (0) after lowering the bias power to the second bias power P2, and thus, the metal electrode 13 is not sputtered.

By this, it is possible to avoid the scattering of the sputtered metal components and the adhesion to the wafer W thereby improving the yield.

Then, after switching to the second bias power P2, as illustrated in FIG. 3C, with that second bias power P2, the etching of the substrate 11 of the dicing region 15 progresses. At this time, because the incident ion energy is lower than when etching of the deposition film 31 due to the reduction in bias power, mainly, etching of the substrate 11 progresses by the action of the radical.

Further, as illustrated in FIG. 2B, the substrate 11 of the dicing region 15 is removed and is diced to a plurality of semiconductor elements 10.

Alternatively, after the etching process, it may switch to the deposition process again, as illustrated in FIG. 3D, so that the film 31 may be deposited again on the bottom and the sidewalls of the dicing region 15. After this deposition process, it switches to the etching process and if the rise (start of Si etching) of the light emission intensity of Si is detected and deposition film 31 is also eliminated at this time, the bias power P2 is reduced to P2 and the etching of the substrate 11 progresses.

Depending on the thickness and the material of the substrate 11, the etching process and the deposition process mentioned above are repeated a plurality of times alternately, and etching can progress in the depth direction by the deposition film 31 reliably suppressing the expansion of the etching width.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A plasma dicing method for plasma etching a substrate at a dicing region between a plurality of semiconductor layers in a wafer, the wafer including the substrate, the plurality of semiconductor layers formed on the substrate separated from each other, metal electrodes provided on each of the semiconductor layers, and a passivation film covering the semiconductor layers, the passivation film having pad openings exposing a portion of the metal electrodes, comprising:
a deposition process depositing a film on the dicing region and on the metal electrodes exposed to the pad opening in an atmosphere containing a plasma of a first gas; and
an etching process etching the film by applying a first bias power to a lower electrode supporting the wafer in an atmosphere containing a plasma of a second gas,
the substrate being etched by reducing the first bias power to a second bias power when light emission due to etching of the substrate at the dicing region is detected during the etching process.

2. The method according to claim 1, wherein an incident ion energy to the wafer when the second bias power is applied to the lower electrode, is lower than an energy to sputter the metal electrode.

3. The method according to claim 1, wherein the substrate at the dicing region is etched by the deposition process and the etching process being alternately repeated a plurality of times.

4. The method according to claim 1, wherein an aspect ratio of the pad opening is less than an aspect ratio of the dicing region.

5. The method according to claim 1, wherein the substrate is a silicon substrate.

6. The method according to claim 1, wherein the first gas includes fluorocarbon-based gas and the second gas includes fluorine-based gas.

7. The method according to claim 6, wherein the first gas includes C₄F₈ and the second gas includes SF₆.

8. The method according to claim 1, wherein the passivation film includes polyimide.

9. The method according to claim 1, wherein the passivation film includes silicon oxide.

10. The method according to claim 1, wherein the metal electrode includes aluminum.

11. A plasma dicing apparatus, comprising:
a processing chamber capable of maintaining a plasma atmosphere;
a lower electrode supporting a wafer in the processing chamber, the wafer including a substrate, a plurality of semiconductor layers formed on the substrate separated from each other, metal electrodes provided on each of the semiconductor layers, and a passivation film covering the semiconductor layers, the passivation film having pad openings exposing a portion of the metal electrode;
a power source applying a bias power to the lower electrode;
a sensor detecting light emission due to etching of the substrate; and
a control unit that can switch between a deposition process and an etching process, the deposition process depositing a film on the dicing region between the plurality of semiconductor layers and the metal electrodes exposed to the pad opening in an atmosphere containing a plasma of a first gas, the etching process etching the film by applying a first bias power to the lower electrode in an atmosphere containing a plasma of a second gas, the control unit reducing the first bias power to a second bias power when etching of the substrate is detected by the sensor during the etching process.

12. The apparatus according to claim 11, wherein an incident ion energy to the wafer when the second bias power is applied to the lower electrode, is lower than an energy to sputter the metal electrode.

13. The apparatus according to claim 11, wherein the control unit switches between the deposition process and the etching process alternately a plurality of times.

14. The apparatus according to claim 11, wherein an aspect ratio of the pad opening is less than an aspect ratio of the dicing region.

15. The apparatus according to claim 11, wherein the substrate is a silicon substrate.

16. The apparatus according to claim 11, wherein the passivation film includes polyimide.

17. The apparatus according to claim 11, wherein the passivation film includes silicon oxide.

18. The apparatus according to claim 11, wherein the metal electrode includes aluminum.
